(19) United States
(12) Patent Application Publication
(10) Pub. No.: US 2010/0288995 A1
(43) Pub. Date: Nov. 18, 2010

(54) SEMICONDUCTOR MEMORY DEVICE AND METHOD OF MANUFACTURING THE SAME

(76) Inventors: Yoshio Ozawa, Kanagawa-ken (JP); Katsuyuki Sekine, Mie-ken (JP); Kazuaki Nakajima, Oita-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/728,028

(22) Filed: Mar. 19, 2010

(30) Foreign Application Priority Data
May 14, 2009 (JP) 2009-117641

(51) Int. Cl. H01L 45/00; H01L 21/20

(52) U.S. Cl. 257/4; 438/482; 257/E45.002; 257/E21.09

(57) ABSTRACT

A semiconductor memory device includes: a lower electrode including a plurality of projections formed on a top surface thereof; an oxide film covering the top surface and made of an oxide of a same metal as a metal contained in the lower electrode; and a resistance variable film provided on the oxide film and being in contact with the oxide film, the projections being buried in the oxide film, and a lower layer portion of the resistance variable film having an oxygen concentration lower than an oxygen concentration of a portion other than the lower layer portion of the resistance variable film.

### CROSS-REFERENCE TO RELATED APPLICATIONS

This application is based upon and claims the benefit of priority from the prior Japanese Patent Application No. 2009-117641, filed on May 14, 2009; the entire contents of which are incorporated herein by reference.

### BACKGROUND

1. Field

Embodiments of the invention relate generally to a semiconductor memory device and a method of manufacturing the same.

2. Background Art

Recently, there has been discovered a metal oxide material whose resistance dramatically changes according to, for example, the voltage applied to the metal oxide material. An idea of a new semiconductor memory device called a resistance random access memory (ReRAM) using the material has been proposed. To reduce the operating voltage of such a ReRAM, a technique has been disclosed in which nanoprojections are formed on the surface of a lower electrode (for example, refer to JP-A 2006-203178 (Kokai)). In the technique described in JP-A 2006-203178 (Kokai), after a thin titanium layer is deposited on a silicon substrate, iridium is deposited by a metal organic chemical vapor deposition (MOCVD) method using methylcyclopentadienyl iridium as a source gas, so that nanoprojections made of iridium oxide are formed.

However, this technique has a limitation in the formation density of the nanoprojections because the nanoprojections are formed by depositing iridium, and also has a problem that the nanoprojections can be formed only on the top surface of a member. Thus, it is difficult to form a sufficient number of projections at a desired position according to the design of a ReRAM. Depending on the design of a ReRAM, the operating voltage thereof cannot be surely and sufficiently reduced.

### SUMMARY

According to an aspect of the invention, there is provided a semiconductor memory device including: a lower electrode including a plurality of projections formed on a top surface thereof; an oxide film covering the top surface and made of an oxide of a same metal as a metal contained in the lower electrode; and a resistance variable film provided on the oxide film and being in contact with the oxide film, the projections being buried in the oxide film, and a lower layer portion of the resistance variable film having an oxygen concentration lower than an oxygen concentration of a portion other than the lower layer portion of the resistance variable film.

According to another aspect of the invention, there is provided a semiconductor memory device including: a resistance variable film; and an upper electrode provided on the resistance variable film and including a plurality of projections formed on a bottom surface thereof, the projections being buried in the resistance variable film.

According to still another aspect of the invention, there is provided a semiconductor memory device including: a first wiring; a first resistance variable film disposed above the first wiring and connected to the first wiring; an upper electrode disposed on the first resistance variable film and including a plurality of projections formed on a bottom surface thereof, the projections being buried in the first resistance variable film; a second wiring disposed on the upper electrode and connected to the upper electrode; a lower electrode disposed above the second wiring, connected to the second wiring, and including a plurality of projections formed on a top surface of the lower electrode; a second resistance variable film disposed on the lower electrode; and a third wiring disposed above the second resistance variable film and connected to the second resistance variable film, the projections formed on the top surface of the lower electrode being buried in the second resistance variable film.

According to still another aspect of the invention, there is provided a method of manufacturing a semiconductor memory device including: forming an amorphous film on a conductive film; forming a polycrystalline conductive film on the amorphous film; and forming a resistance variable film containing oxygen on the polycrystalline conductive film and reacting an element contained in the polycrystalline conductive film with the oxygen contained In the resistance variable film while growing crystals of the polycrystalline conductive film.

According to still another aspect of the invention, there is provided a method of manufacturing a semiconductor memory device including: forming an amorphous film on a conductive film; forming a polycrystalline conductive film on the amorphous film; nitriding at least crystal grain boundaries of the polycrystalline conductive film; and forming a resistance variable film containing oxygen on the polycrystalline conductive film and reacting an element contained in the polycrystalline conductive film with the oxygen contained in the resistance variable film.

According to still another aspect of the invention, there is provided a method of manufacturing a semiconductor memory device including: forming a resistance variable film; and forming a polycrystalline conductive film on the resistance variable film and growing crystals of the polycrystalline conductive film.

According to still another aspect of the invention, there is provided a method of manufacturing a semiconductor memory device including: forming a resistance variable film made of any one of hafnium oxide containing zirconium and titanium oxide containing zirconium; forming a silicon film on the resistance variable film; and reacting the zirconium in the resistance variable film with silicon in the silicon film.

According to still another aspect of the invention, there is provided a method of manufacturing a semiconductor memory device including: forming a base film of a resistance variable film; forming a metal silicate film on the base film;

phase-separating the metal silicate film into a portion made of a metal oxide and a portion made of silicon oxide by heating; removing the portion made of the silicon oxide; and forming an upper electrode on the base film to cover the portion made of the metal oxide.

### BRIEF DESCRIPTION OF THE DRAWINGS

FIG. 1 is a perspective view illustrating a semiconductor memory device according to a first embodiment of the invention;

FIG. 2 is a cross-sectional view illustrating a portion of the semiconductor memory device shown in FIG. 1;

FIG. 3 is a cross-sectional view illustrating a resistance variable element shown in FIG. 2;

FIGS. 4A to 4C are process cross-sectional views illustrating a method of manufacturing the semiconductor memory device according to the first embodiment;

FIGS. 5A and 5B are cross-sectional views illustrating variations of the first embodiment, respectively;

FIGS. 6A to 6C are process cross-sectional views illustrating a method of manufacturing a semiconductor memory device according to a second embodiment of the invention;

FIG. 7 is a cross-sectional view illustrating a portion of a semiconductor memory device according to a third embodiment of the invention;

FIGS. 8A to 8C are process cross-sectional views illustrating a method of manufacturing the semiconductor memory device according to the third embodiment;

FIGS. 9A to 9C are process cross-sectional views illustrating a method of manufacturing a semiconductor memory device according to a fourth embodiment of the invention;

FIGS. 10A to 10C are process cross-sectional views illustrating a method of manufacturing a semiconductor memory device according to a fifth embodiment of the invention; and

FIG. 11 is a cross-sectional view illustrating a portion of a semiconductor memory device according to a sixth embodiment of the invention.

### DETAILED DESCRIPTION

In the following, embodiments of the invention are described with reference to the drawings.

First of all, a first embodiment of the invention is described.

A semiconductor memory device according to the first embodiment is a resistance random access memory (ReRAM).

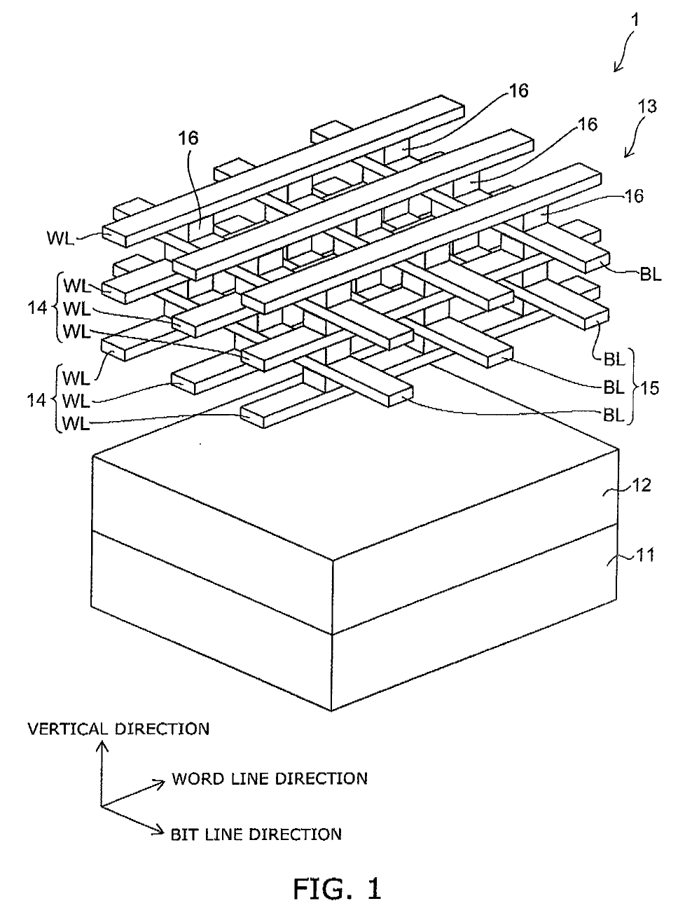

FIG. 1 is a perspective view illustrating the semiconductor memory device according to the first embodiment.

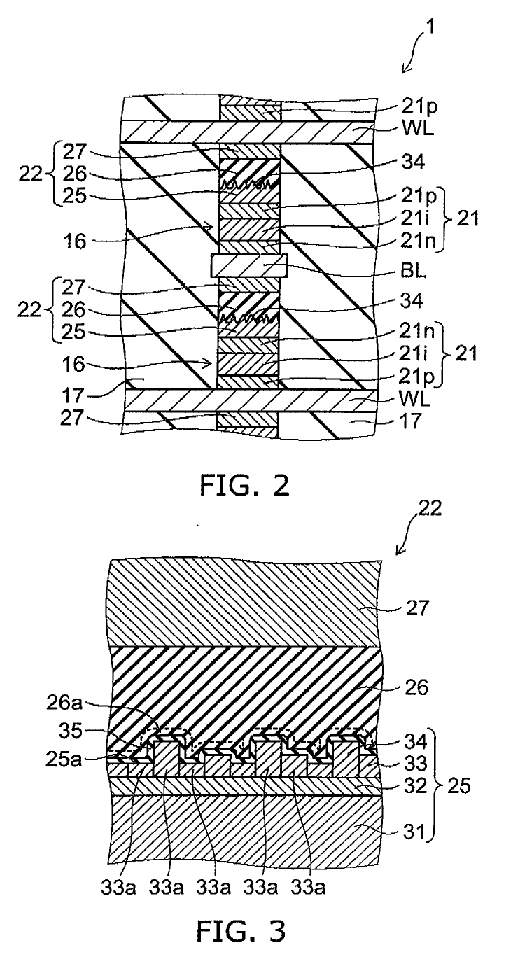

FIG. 2 is a cross-sectional view illustrating a portion of the semiconductor memory device shown in FIG. 1.

FIG. 3 is a cross-sectional view illustrating a resistance variable element shown in FIG. 2.

A feature of the semiconductor memory device according to the first embodiment Is as follows. Specifically, each memory cell includes a resistance variable element, which is configured by stacking a lower electrode, a resistance variable film, and an upper electrode in this order; nanoprojections, which are buried in the resistance variable film, are formed on the top surface of the lower electrode; and the lowest layer portion, i.e., a portion close to the lower electrode, of the resistance variable film is an oxygen deficiency layer. In the following, the entire configuration of the semiconductor memory device according to the first embodiment is briefly described, and then the above-mentioned feature is described in detail.

As shown in FIG. 1, a semiconductor memory device 1 according to the first embodiment is provided with a silicon substrate 11. A drive circuit (not shown) of semiconductor memory device 1 is formed in the upper layer part and on the top surface of the silicon substrate 11. An interlayer insulating film 12 made of silicon oxide, for example, is provided on the silicon substrate 11 in a way that the drive circuit is buried in the interlayer insulating film 12. A memory cell portion 13 is provided on the interlayer insulating film 12.

In the memory cell portion 13, word line wiring layers 14 and bit line wiring layers 15 are alternately stacked with an insulating layer 17 (see FIG. 2) thereamong. Each of the word line wiring layers 14 includes multiple word lines WL extending in a direction parallel to the top surface of the silicon substrate 11 (hereinafter referred to as “word line direction”). Each of the bit line wiring layers 15 includes multiple bit lines BL extending in a direction parallel to the top surface of the silicon substrate 11 and intersecting, e.g., perpendicular to, the word line direction (hereinafter referred to as “bit line direction”). The word lines WL and the bit lines BL are made of an electric conductor, for example, a metal. There is no contact between the word lines WL, between the bit lines BL, and between the word line WL and the bit line BL. At the portion where the distance between one word line WL and one bit line BL is the shortest, there is provided a pillar 16, which extends in a direction perpendicular to the top surface of the silicon substrate 11 (hereinafter referred to as “vertical direction”). The word lines WL, the bit lines BL, and the pillars 16 are buried in the insulating layer 17.

As shown in FIG. 2, a diode 21 is provided in the lower portion of the pillar 16, while a resistance variable element 22 is provided in the upper portion of the pillar 16. The diode 21 is made of a semiconductor material, silicon, for example. The diode 21 is configured by stacking a p type layer 21p, an i type layer 21i, and an n type layer 21n on one another. The order of stacking the p type layer 21p, the i type layer 21i, and the n type layer 21n differ from one location to others, depending on where the pillar 16 is disposed. The p type layer 21p is disposed on the word line WL side, and the n type layer 21n is disposed on the bit line BL side. The i type layer 21i is disposed between the p type layer 21p and the n type layer 21n. In the resistance variable element 22, a lower electrode 25, a resistance variable film 26, and an upper electrode 27 are stacked in this order from the bottom layer side. The resistance variable film 26 is a film whose electrical resistance changes according to a voltage applied to the resistance variable film 26 and its hysteresis. The resistance variable film 26 is made of, for example, a metal oxide such as nickel oxide. The word line WL and the bit line BL may contact with the upper electrode 27 of the pillar 16 provided the word line WL and the bit line BL, and do not need to contact with it.

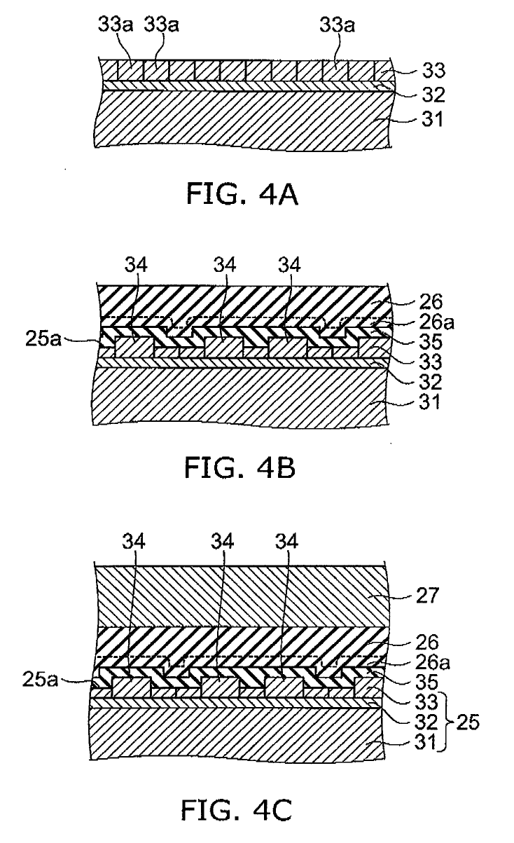

Next, features of the first embodiment are described. As shown in FIGS. 2 and 3, in the lower electrode 25, a conductive film 31 made of tungsten, for example, is provided. On the conductive film 31, an amorphous film 32, which is made of, for example, titanium silicon nitride and has an amorphous crystal structure, is provided. On the amorphous film 32, a polycrystalline conductive film 33, which is made of, for example, titanium nitride and has a polycrystalline structure, is provided. The top surface of the polycrystalline conductive film 33 is a top surface 25a of the lower electrode 25. In FIG. 3, the crystal grain boundaries of the polycrystalline conductive film 33 is schematically illustrated by straight lines. Each crystal grain 33a is schematically shown as a polygon (rectangle in FIG. 3) formed by the multiple straight lines. In FIGS. 4A to 5B, and 7 described later, the crystal grains 33a are shown similarly to FIG. 3.

Multiple projections 34 are formed on the top surface 25a of the lower electrode 25. The heights of the respective projections 34 are, for example, 0.3 to 3 nm. The formation density of the projections 34 is not less than 10000 projections/μm². On a single layer of the lower electrode 25, e.g., 10 or more projections 34 are formed. Seen from the above, the distribution and shape of the projections 34 correspond to those of the crystal grains 33a of the polycrystalline conductive film 33. In other words, the projections 34 are formed of a subset of the multiple crystal grains 33a that form the top surface 25a of the lower electrode 25, the subset projecting above the crystal grains surrounding the subset. Each projection 34 has a corner portion or a curved surface portion with a small radius of curvature formed on the top.

On the lower electrode 25, an oxide film 35 made of, for example, titanium oxide, is provided. The oxide film 35 has a film thickness of 0.2 to 2 nm, for example, and is curved, reflecting the shape of the projections 34. The oxide film 35 is in contact with the resistance variable film 26. Accordingly, the projections 34 are buried in the oxide film 35 as well as into the resistance variable film 26 via the oxide film 35.

A lower layer portion 26a, i.e., a portion in contact with the oxide film 35, of the resistance variable film 26 has an oxygen concentration lower than an oxygen concentration of the other portion of the resistance variable film 26. An example shows that the thickness of the lower layer portion 26a is approximately the same as the thickness of the oxide film 35, and the lower layer portion 26a has an oxygen concentration approximately 10 to 20% lower than an oxygen concentration of the portion other than the lower layer portion 26a of the resistance variable film 26. Accordingly, in the lower layer portion 26a, oxygen deficiency occurs where oxygen is removed from the crystal lattice of nickel oxide, and the lower layer portion 26a is an oxygen deficiency layer.

Next, a method of manufacturing a semiconductor memory device according to the first embodiment is described.

FIGS. 4A to 4C are process cross-sectional views illustrating the method of manufacturing a semiconductor memory device according to the first embodiment.

A feature of the method of manufacturing a semiconductor memory device according to the first embodiment is that the polycrystalline conductive film 33 is formed on the amorphous film 32, and heat treatment is applied to the polycrystalline conductive film 33 to grow crystals of the polycrystalline conductive film 33, thereby forming the projections 34. Another feature of the method is that an oxygen deficiency layer is formed in a lower layer portion of the resistance variable film 26 by the heat treatment, which forms the oxide film 35 between the polycrystalline conductive film 33 and the resistance variable film 26. In the following, the detail is described.

First, as shown in FIG. 1, the silicon substrate 11 is prepared. A drive circuit (not shown) is then formed in an upper layer portion and on the top surface of the silicon substrate 11. Next, silicon oxide, for example, is deposited on the silicon substrate 11 to form an interlayer insulating film 12 in a way that the drive circuit is buried in the interlayer insulating film 12. Subsequently, the memory cell portion 13 is produced on the interlayer insulating film 12. The memory cell portion 13 is produced by alternately forming the word line wiring layer 14 or the bit line wiring layer 15 and the multiple pillars 16.

In the following, a method of forming the pillar 16 is described.

First, with reference to FIG. 2, the top surface of the word line WL formed by the previous process is exposed from the top surface of the insulating layer 17. Then, the p type layer 21p, the i type layer 21i, and the n type layer 21n are deposited in this order to form the diode 21 on the top surface of the word line WL.

Next, as shown in FIG. 4A, tungsten is deposited to a thickness of 100 nm by a physical vapor deposition (PVD) method to form the conductive film 31. Subsequently, titanium silicon nitride is deposited to a thickness of 1 nm by a PVD or atomic layer deposition (ALD) method, for example, to form the amorphous film 32. Thereafter, titanium nitride is deposited by a chemical vapor deposition (CVD) method, for example, to form the polycrystalline conductive film 33. At this stage, since the underlying layer of the polycrystalline conductive film 33 is the amorphous film 32, the crystallinity of the polycrystalline conductive film 33 is not affected by the crystallinity of the conductive film 31. Thus, a polycrystalline film with a random orientation of crystals having a small average grain diameter can be formed.

The average crystal grain diameter of the polycrystalline conductive film 33 can be controlled by changing the ratio of the source-gas amount to be supplied, the temperature, and the thickness of the film to be formed. Specifically, the lower the ratio of the metal-source-gas flow amount to the entire source-gas amount is, the smaller average crystal grain diameter is obtained. When the ratio of the metal-source-gas flow amount is decreased to near its lower limit, the average crystal grain diameter can be reduced to approximately ½ to ⅓ of that obtained when the ratio of the metal-source-gas flow amount is increased to near its upper limit. Also, the lower the temperature is, the smaller average crystal grain diameter is obtained. When the temperature is decreased to near its lower limit, the average crystal grain diameter can be reduced to approximately ½ of that obtained when the temperature is increased to near its upper limit. In addition, since the average crystal grain diameter is approximately proportional to the thickness of the film to be formed, the thinner the film is, the smaller average crystal grain diameter is obtained. In the first embodiment, titanium tetrachloride gas and ammonia gas are used as source gases and titanium nitride is deposited to a film thickness of approximately 5 nm at 600° C., for example. Under this condition, the resultant average crystal grain diameter of the polycrystalline conductive film 33 is approximately 1 to 5 nm. The lower electrode 25 is formed by the conductive film 31, the amorphous film 32, and the polycrystalline conductive film 33.

Next, as shown In FIG. 4B, by a PVD method, which is performed in an oxidizing atmosphere such as oxygen gas or water vapor, or a so-called reactive sputtering method, the resistance variable film 26 is formed by depositing nickel oxide to a thickness of 10 nm on the polycrystalline conductive film 33. Since the resistance variable film 26 is formed of nickel oxide, the resistance variable film 26 contains oxygen.

Next, heat treatment is applied to the polycrystalline conductive film 33 in a non-oxidizing atmosphere such as a nitrogen atmosphere or in a reducing atmosphere such as a hydrogen atmosphere, so that the polycrystalline conductive film 33 is heated up to a temperature of e.g. 400 to 800° C. Thereby, the crystal grains 33a of the polycrystalline conductive film 33 are grown. However, the degree and orientation of the growth of the crystal grains are irregular among the crystal grains because the degree and orientation of the growth depend on the crystal orientation and the like of each crystal grain 33a. Thus, the projections 34 are formed from the crystal grains 33a, which have been grown upward more than the surrounding crystal grains 33a of the polycrystalline conductive film 33 and which project above the surrounding surface and are buried in the resistance variable film 26.

During the heat treatment, titanium contained in the polycrystalline conductive film 33 made of titanium nitride reacts with oxygen contained in the resistance variable film 26 made of nickel oxide to form the oxide film 35 made of titanium oxide between the polycrystalline conductive film 33 and the resistance variable film 26. The oxide film 35 having a film thickness of e.g. 0.2 to 2 nm is formed so as to cover the projections 34. As the formation of the oxide film 35 proceeds, part of the oxygen contained in the resistance variable film 26 is incorporated into the oxide film 35. Thus, the lower layer portion 26a of the resistance variable film 26 becomes an oxygen deficiency layer. In other words, the lower layer portion 26a becomes a metal-rich layer.

During the heat treatment, the height of the projection 34 and the thickness of the oxide film 35 can be controlled by adjusting the condition in which the resistance variable film 26 is formed as well as the condition for the subsequent heat treatment. For example, if the sputtering rate for the resistance variable film 26 is reduced, the oxygen concentration in the resistance variable film 26 is increased to form thicker oxide film 35. Meanwhile, if the heat treatment is applied at a higher temperature for a longer period, the crystal growth of the polycrystalline conductive film 33 is promoted, and the height of the projection 34 is increased. The crystal growth is more promoted by heating in a reducing atmosphere than by heating in a non-oxidizing atmosphere. As described above, in the first embodiment, the atmosphere, temperature, time period, and the like for the heat treatment are adjusted in a way that the projection 34 has a height of approximately 0.3 to 3 nm, and that the oxide film 35 has a film thickness of approximately 0.2 to 2 nm.

Next, as shown in FIG. 4C, the upper electrode 27 is formed on the resistance variable film 26 by depositing tungsten to a thickness of 100 nm by a PVD method, for example. The resistance variable element 22 is formed by the lower electrode 25, the resistance variable film 26, and the upper electrode 27. Subsequently, the resistance variable element 22 and the diode 21 are processed into a pillar-like structure to form the pillar 16 by a lithography technique or reactive ion etching (RIE), for example.

After that, the pillar 16 is buried in the insulating layer 17. Then, the bit line BL is formed on the pillar 16, another pillar 16 is formed again, and the word line WL is formed thereon. By repeating these processes, the memory cell portion 13 is produced and the semiconductor memory device 1 is manufactured.

Next, the operation in the first embodiment is described.

By applying the ground potential to one word line WL and a positive potential to one bit line BL, a voltage is applied to the pillar 16 connected between the word line WL and the bit line BL. At this point, a forward voltage is applied to the diode 21. Thus, the voltage cannot be held at the diode 21 and is applied to the oxide film 35 and the resistance variable film 26, which are included in the pillar 16.

At this time, the nanoprojections 34 are formed on the top surface 25a of the lower electrode 25 and buried in the oxide film 35. Thus, current paths starting from the projections 34 are created in the inside of the oxide film 35 and the resistance variable film 26. The length of the current paths is shorter with the formation of the projections 34 than without the projections. Also due to the projection shape, which has the corner portion or curved surface portion with a small radius of curvature, an electric field is increased locally. Accordingly, a lower voltage causes a current to flow, and the operating voltage of the semiconductor memory device 1 can be reduced. In addition, the operating current can be reduced because a current flows along the current path locally.

Next, effects of the first embodiment are described.

In the first embodiment, since the polycrystalline conductive film 33 is formed on the amorphous film 32 serving as the underlying layer, the polycrystalline conductive film 33 has a smaller average crystal grain diameter and a random crystal orientation. By applying the heat treatment to the polycrystalline conductive film 33 after the resistance variable film 26 is formed thereon, the crystal grains 33a of the polycrystalline conductive film 33 are nonuniformly grown to form the projections 34. Consequently, the nanoprojections 34 can be formed with a high density. For example, the height of the projection 34 can be 0.3 to 3 nm, and the formation density of the projections 34 can be not less than 10000 projections/μm².

Even if the pillar 16 is made thinner and the memory cell is miniaturized, it is possible to surely form more than a certain number of the projections 34 in the lower electrode 25 of each pillar 16. Thus, the operating voltage can be surely reduced. Since it is possible to form multiple current paths in the resistance variable film 26 by forming multiple projections 34 in each lower electrode 25, the resistance of the whole resistance variable film 26 can be selected from three or more levels by switching resistances between the current paths. Accordingly, variable range of the resistance of the whole resistance variable film 26 is increased, enabling multi level memory operation. In other words, if at least one projection is present in each memory cell, for example, the operating voltage and the operating current can be reduced. If each memory cell has three or more projections, four or more resistance levels can be easily implemented; thus, multi level operation of the memory cell can be achieved. Furthermore, the resistance variable film 26 can be thinly formed by suppressing the height of the projection 34, and thereby an increase of the aspect ratio of the pillar 16 can be prevented.

On the other hand, with the technique described in JP-A 2006-203178 (Kokai) mentioned above, it is difficult to form projections with a high density with the heights of the projections being lowered. For example, if the width of the pillar is made 50 nm or less, in order to form 10 or more projections in the lower electrode provided in one pillar, the formation density of projections needs to be 4000 projections/μm² or more. However, in this case, according to the technique described in JP-A 2006-203178 (Kokai) mentioned above, the height of the projections will be 100 nm or more, and the aspect ratio of each pillar is increased. If the aspect ratio of each pillar is increased, a variation in the shapes of the produced pillars is increased and a malfunction of produced memory tends to occur.

In the first embodiment, with the heat treatment to grow the polycrystalline conductive film 33, the metallic element in the polycrystalline conductive film 33 reacts with the oxygen element in the resistance variable film 26 to form the oxide film 35. Since oxygen in the resistance variable film 26 is consumed during the heat treatment, a high degree of oxygen deficiency occurs in the lower layer portion 26a of the resistance variable film 26. Accordingly, the current path is more likely to be formed In the resistance variable film 26. Thus, the operating voltage is further reduced.

Furthermore, in the first embodiment, the amorphous film 32 is formed of titanium silicon nitride, which has a relatively lower electrical resistivity, and can keep its amorphous state even after a high temperature heat treatment of 1000° C. or so. Therefore, the amorphous film 32 is not crystallized at the time of deposition of the polycrystalline conductive film 33. Also, the electrical resistance of the lower electrode 25 is not excessively increased.

Still furthermore, in the first embodiment, the polycrystalline conductive film 33 is formed of titanium nitride, which easily combines with oxygen. Thus, a high degree of oxygen deficiency occurs in the resistance variable film 26.

Still furthermore, in the first embodiment, the formation of the projections due to the crystal growth and the formation of the oxygen deficiency layers due to the oxidation reaction are achieved by the same heat treatment. Therefore, characteristic fluctuation of the drive circuit due to excessive heat treatment can be avoided. Furthermore, the manufacturing process can be simplified and the manufacturing cost can be reduced.

It should be noted that, in the first embodiment, there has been shown an example where the heat treatment is applied in a reducing atmosphere or in a non-oxidizing atmosphere to grow the crystal grains of the polycrystalline conductive film 33; however, the heat treatment may be applied in an oxidizing atmosphere such as an oxygen atmosphere or a water vapor atmosphere. Before the resistance variable film is formed, the polycrystalline conductive film 33 may be heated in an oxidizing atmosphere to form projections. In these cases, since the crystal growth of the polycrystalline conductive film 33 is promoted and the height of the projections is increased, the operating voltage and operating current can be further reduced. However, the degree of oxygen deficiency generated in the resistance variable film is reduced. Thus, it is preferable to set the partial pressure of the oxidizing agent to be 1 kPa or less, for example, to secure a certain degree of oxygen deficiency. Even if the above-mentioned heat treatment is omitted, the projections 34 and the oxide film 35 can be formed when the resistance variable film 26 is formed at a temperature of not lower than 200° C.

The amorphous film 32 may be formed of an amorphous insulating material such as a silicon nitride film or a silicon oxide film. Alternatively, the surface of the conductive film 31 may be oxidized or nitrided to form the amorphous film. However, if the amorphous film 32 is formed by using an insulating material, it is desirable for the amorphous film 32 to have a film thickness of 1 nm or less so that the electrical resistance of the lower electrode 25 may not be excessively increased. Also, the polycrystalline conductive film 33 may be formed of silicon (doped silicon) containing an element used as a dopant. In this case, the oxide film 35 becomes a silicon oxide film.

Still furthermore, in the first embodiment, there has been shown an example where the resistance variable film 26 is formed of nickel oxide. However, the material for forming the resistance variable film 26 is not limited to the nickel oxide, and the resistance variable film 26 may be formed of a transition metal oxide, such as titanium oxide, cobalt oxide, hafnium oxide, tantalum oxide, and tungsten oxide. In this case, it is preferable to select a material so that the dielectric constant of the resistance variable film 26 is greater than the dielectric constant of the oxide film 35 because electric current can flow easily from the projection 34 when a voltage is applied to the resistance variable element 22.

Still furthermore, in the first embodiment, there has been shown an example where the resistance variable film 26 is formed in an oxidizing atmosphere by a PVD method, but the invention is not limited to this example. The resistance variable film 26 may be formed by an ALD or CVD method using an oxidizing gas such as oxygen, water vapor, and ozone.

Still furthermore, in the first embodiment, there has been shown an example where the diode 21 is provided in the lower portion of the pillar 16, and the resistance variable element 22 is provided in the upper portion of the pillar 16. However, the configuration of the pillar 16 is not limited to this, and the resistance variable element may be provided in the lower portion of the pillar, and the diode may be provided in the upper portion of the pillar.

Next, variations of the first embodiment are described.

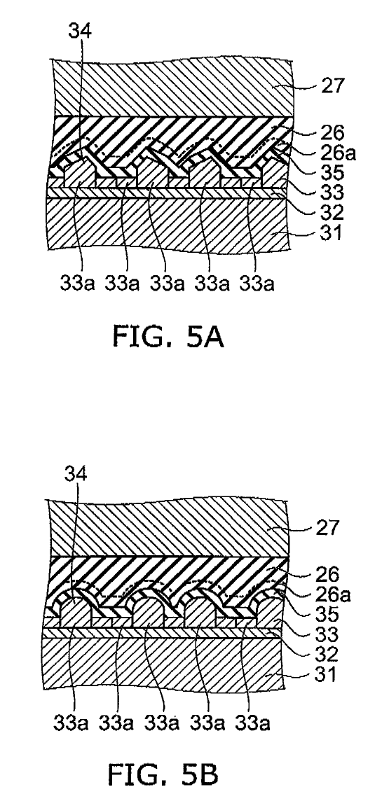

FIGS. 5A and 5B are cross-sectional views illustrating variations of the first embodiment, respectively.

In the first embodiment, the crystal grain 33a of the polycrystalline conductive film 33 is schematically shown in a rectangular shape in FIG. 3. However, the crystal grain 33a is not limited to the rectangular shape. In other words, the shape of the crystal grain 33a may be substantially rectangular as shown in FIG. 3, but the crystal grain 33a may have a corner portion pointing upward as shown in FIG. 5A, or an upward convex curved surface as shown in FIG. 5B. Alternatively, the crystal grain 33a may take a shape other than the shapes shown in FIGS. 3, 5A, and 5B. In all these cases, the same effects as those in the first embodiment can be achieved. In particular, as shown in FIGS. 5A and 5B, when the crystal grain 33a has a corner portion pointing upward or an upward convex curved surface, an electric field concentrates on the corner portion or the curved surface. Thus, an electric current flows more easily in the current paths formed in the resistance variable film 26. Accordingly, the operating voltage and operating current can be further reduced.

Next, a second embodiment of the invention is described.

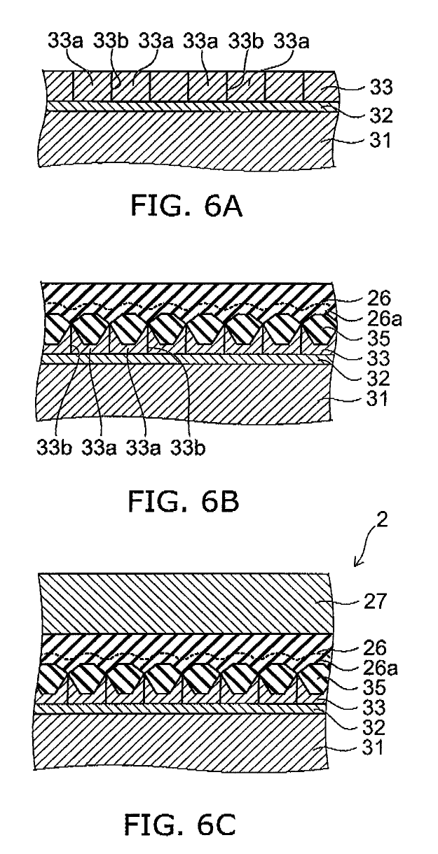

FIGS. 6A to 6C are process cross-sectional views illustrating a method of manufacturing a semiconductor memory device according to the second embodiment.

The configuration of a semiconductor memory device 2 according to the second embodiment is similar to that of the first embodiment. In the first embodiment described above, the distribution and shape of the projections 34 seen from the above correspond to those of the crystal grains 33a of the polycrystalline conductive film 33; however, in the second embodiment, the distribution and shape correspond to those of crystal grain boundaries 33b of the polycrystalline conductive film 33. Specifically, in the upper surface of the polycrystalline conductive film 33, a portion including the crystal grain boundaries 33b project above the inside of the crystal, and at least a part of the portion forms the projection 34. Accordingly, the projections 34 are arranged along the crystal grain boundaries 33b of the crystal grains 33a that form the top surface 25a of the lower electrode 25.

In the following, described is a production method of a resistance variable element, which is a part of the method of manufacturing a semiconductor memory device according to the second embodiment.

First, as shown in FIG. 6A, a conductive film 31 is formed by depositing tungsten to a thickness of 100 nm by a PVD method, for example. Next, titanium silicon nitride is deposited to a thickness of 1 nm by a PVD or ALD method, for example, to form an amorphous film 32. Then, doped silicon is deposited by a CVD method, for example, to form a polycrystalline conductive film 33 on the amorphous film 32. At this stage, since the amorphous film 32 is formed as the underlying layer of the polycrystalline conductive film 33, the crystallinity of the polycrystalline conductive film 33 is not affected by the crystallinity of the conductive film 31. Thus, a polycrystalline film with a random orientation of crystals having a small average particle diameter can be formed.

The average crystal grain diameter of the polycrystalline conductive film 33 can be controlled by changing the temperature, a thickness of the film to be formed, and the like. Specifically, the lower the temperature is, the smaller average crystal grain diameter is obtained. Also, the thinner the film is, the smaller average crystal grain diameter is obtained. For example, when dichlorosilane and phosphine are used as source gases, and doped silicon is deposited to a film thickness of approximately 5 nm at a temperature of 600 to 700° C., the resultant average crystal grain diameter of the polycrystalline conductive film 33 is approximately 3 to 5 nm.

Next, heat treatment is applied to the polycrystalline conductive film 33 in a nitrogen monoxide gas atmosphere, so that the polycrystalline conductive film 33 heated up to a temperature of 800 to 1000° C. Thereby, a silicon oxynitride film (not shown) is formed on the surface of the polycrystalline conductive film 33, while the nitrogen element is introduced into the crystal grain boundaries 33b of the polycrystalline conductive film 33. In the heat treatment, it is sufficient for at least the crystal grain boundary of the polycrystalline conductive film 33 to be nitrided. Subsequently, a silicon oxynitride film is removed by using e.g., dilute hydrofluoric acid.

Next, as shown in FIG. 6B, by a PVD method (chemical sputtering method), which is performed in an oxidizing atmosphere such as oxygen gas or water vapor, a resistance variable film 26 containing oxygen is formed by depositing nickel oxide to a thickness of 10 nm on the polycrystalline conductive film 33.

Next, the polycrystalline conductive film 33 is heated up to a temperature of e.g. 400 to 800° C. in a non-oxidizing atmosphere such as a nitrogen atmosphere or in a reducing atmosphere such as a hydrogen atmosphere. Thereby, silicon in the polycrystalline conductive film 33 reacts with oxygen in the resistance variable film 26 to form an oxide film 35 made of silicon oxide between the polycrystalline conductive film 33 and the resistance variable film 26. Since the nitrogen element has been introduced into the crystal grain boundaries 33b of the polycrystalline conductive film 35, the oxidizing rate at the crystal grain boundary 33b is lower than that inside of the crystal grain 33a during the reaction. Accordingly, the inside of the crystal grain 33a of the polycrystalline conductive film 33 is selectively oxidized, and the portion including the crystal grain boundaries 33b is relatively projected above the inside of the crystal grain, so that a projection 34 is formed in the upper surface of the polycrystalline conductive film 33. Seen from the above, the projections 34 are arranged along the crystal grain boundaries 33b of the crystal grains 33a that form the upper surface of the polycrystalline conductive film 33. These projections 34 are buried in the oxide film 35.

As the formation of the oxide film 35 proceeds, part of oxygen contained in the resistance variable film 26 is incorporated into the oxide film 35. Thus, a lower layer portion 26a of the resistance variable film 26 becomes an oxygen deficiency layer. It should be noted that, even if the above-mentioned heat treatment is omitted, the projections 34 and the oxide film 35 as well as the oxygen deficiency layer can be formed when the resistance variable film 26 is formed at a temperature of not lower than 200° C.

Next, as shown in FIG. 6C, an upper electrode 27 is formed on the resistance variable film 26 by depositing tungsten to a thickness of 100 nm by a PVD method, for example. Subsequent processes are the same as those of the first embodiment described above. The configurations, manufacturing methods, and operations, other than described above, of the second embodiment are the same as those of the first embodiment described above. In the second embodiment as well, the same effects as those of the first embodiment described above can be achieved.

Next, a third embodiment of the invention is described.

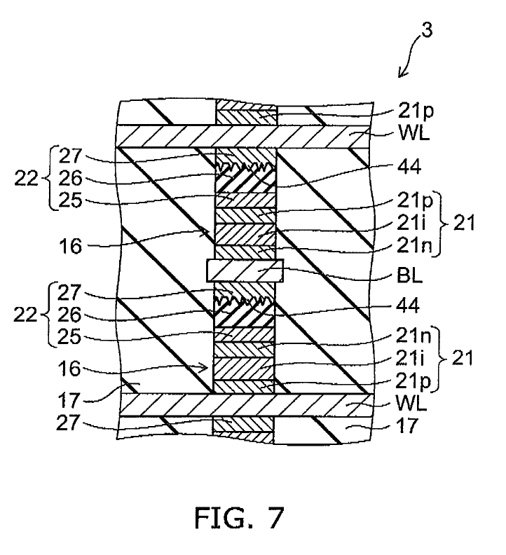

FIG. 7 is a cross-sectional view illustrating a portion of a semiconductor memory device according to the third embodiment.

The semiconductor memory device according to the third embodiment is a resistance random access memory (ReRAM).

As shown in FIG. 7, a feature of a semiconductor memory device 3 according to the third embodiment is that each memory cell includes a resistance variable element 22, which is configured by stacking a lower electrode 25, a resistance variable film 26, and an upper electrode 27 in this order; and nanoprojections 44 buried in the resistance variable film 26 are formed in a bottom surface 27a of the upper electrode 27. The entire configuration of the semiconductor memory device 3 according to the third embodiment is the same as that of the first embodiment described above. Specifically, as shown in FIG. 1, a memory cell portion 13 is provided on a silicon substrate 11 with an interlayer insulating film 12 interposed between the memory cell portion 13 and the silicon substrate 11. In the memory cell portion 13, a pillar 16 is provided at each portion where the distance between one word line WL and one bit line BL is the shortest. In the following, the above-mentioned feature is described in detail.

As shown in FIG. 7, a diode 21 is provided in the lower portion of the pillar 16, while a resistance variable element 22 is provided in the upper portion of the pillar 16. The configuration of the diode 21 is the same as that of the first embodiment described above. On the other hand, in the resistance variable element 22, a lower electrode 25, a resistance variable film 26, and an upper electrode 27 are stacked in this order from the bottom layer side.

Multiple projections 44 are formed in the bottom surface 27a of the upper electrode 27. The heights of the respective projections 44 are, for example, 0.3 to 3 nm, and the formation density of the projections 44 is not less than 1000 projections/μm², for example, 10000 projections/μm². The projections 44 are formed of a subset of multiple crystal grains that form the bottom surface of a polycrystalline conductive film 43, and the subset projecting below the crystal grains surrounding the subset. The projections 44 are buried in the inside of the resistance variable film 26. However, in the third embodiment, unlike the first embodiment, an oxide film is not substantially formed between the resistance variable film 26 and the upper electrode 27. Moreover, in the resistance variable film 26, an oxygen deficiency layer is not substantially formed. The configurations other than described above of the third embodiment are the same as those of the first embodiment described above.

Next, a method of manufacturing a semiconductor memory device according to the third embodiment is described.

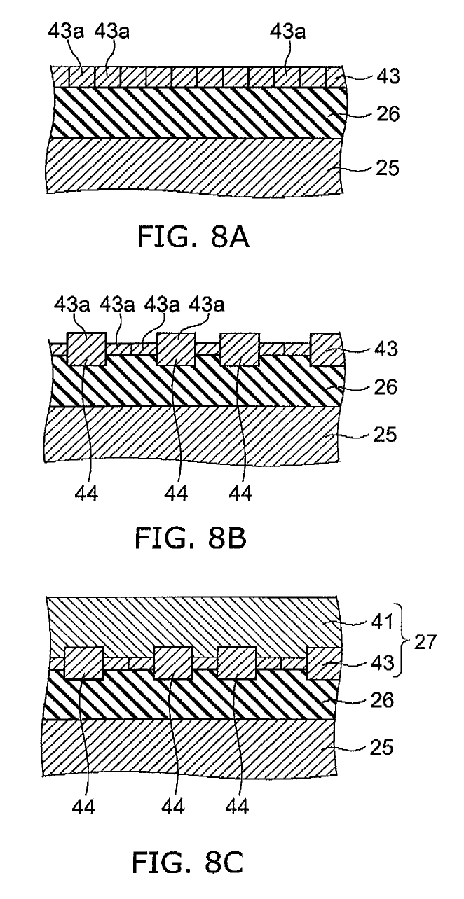

FIGS. 8A to 8C are process cross-sectional views illustrating the method of manufacturing a semiconductor memory device according to the third embodiment.

A feature of the method of manufacturing the semiconductor memory device according to the third embodiment is that the polycrystalline conductive film 43 is formed on the resistance variable film 26, and crystal growth is promoted in the polycrystalline conductive film 43 to form the projections 44. In the following, described is a production method of a resistance variable element, which is a part of the method of manufacturing a semiconductor memory device according to the third embodiment.

First, as shown in FIG. 8A, a lower electrode 25 is formed by depositing tungsten to a thickness of 100 nm by a PVD method, for example. Next, nickel oxide is deposited to a thickness of 10 nm on the lower electrode 25 by a PVD method, for example, to form a resistance variable film 26 with an amorphous structure.

Next, titanium nitride is deposited by a CVD method, for example, to form a polycrystalline conductive film 43. At this stage, since the resistance variable film 26 with an amorphous structure is formed as the underlying layer of the polycrystalline conductive film 43, the crystal structure of the polycrystalline conductive film 43 is not affected by the crystal structure of the lower electrode 25. Thus, the average particle diameter of the crystal grain 43a can be reduced, and a random orientation of crystals can be achieved. Similarly to the first embodiment described above, the crystal grain diameter of the polycrystalline conductive film 43 can be controlled by adjusting the ratio of the source-gas amount to be supplied, and the thickness of the film to be formed. For example, if titanium tetrachloride gas and ammonia gas are used as source gases for CVD and titanium nitride is deposited to a film thickness of approximately 5 nm, the resultant average crystal grain diameter of the polycrystalline conductive film 43 is approximately 1 to 5 nm.

Next, as shown in FIG. 8B, heat treatment is applied to the polycrystalline conductive film 43 in a non-oxidizing atmosphere such as a nitrogen atmosphere or in a reducing atmosphere such as a hydrogen atmosphere, so that the polycrystalline conductive film 43 is heated up to a temperature of e.g. 400 to 800° C. Thereby, the respective crystal grains 43a of the polycrystalline conductive film 43 are grown. However, the degree and orientation of the growth of the crystal grains are irregular among the crystal grains because the degree and orientation of the growth depend on the crystal orientation and the like of each crystal grain 43a. Thus, the projections 44 are formed from the crystal grain 43a, which have been grown downward more than the surrounding crystal grains 43a that form the bottom surface of the polycrystalline conductive film 43 and which projects below the surrounding surface and are buried in the resistance variable film 26. Similarly to the first embodiment described above, the height of the projection 44 can be controlled by adjusting the condition for the heat treatment.

Next, as shown in FIG. 8C, a conductive film 41 is formed on the resistance variable film 26 by depositing tungsten to a thickness of 100 nm by a PVD method, for example. Accordingly, an upper electrode 27 is formed from the polycrystalline conductive film 43 and the conductive film 41. Subsequent processes of the manufacturing method are the same as those of the first embodiment described above.

Next, effects of the third embodiment are described.

According to the third embodiment, the projections 44 can be formed in the bottom surface of the upper electrode 27 instead of the upper surface of the lower electrode 25. The semiconductor memory device according to the third embodiment is a monopolar type resistance random access memory (ReRAM), and an electronic current flows through the resistance variable film 26. Thus, in the resistance variable film 26, current paths can be formed more efficiently with the projections 44 provided on the side of an electrode, which emits electrons to the resistance variable film 26, i.e., negative electrode side, than with the projections 44 provided on the positive electrode side. In the third embodiment, since the projections 44 can be formed in the bottom surface 27a of the upper electrode 27, a wiring arranged on the upper side with respect to the resistance variable film 26 can be used as a negative electrode.

On the other hand, with the technique described in JP-A 2006-203178 (Kokai) mentioned above, a projection can be formed only on the upper surface of the lower electrode, and cannot be formed on the lower surface of the upper electrode. For this reason, the direction of a voltage applied to the resistance variable film is limited to the direction defined by the condition that the lower side of the resistance variable film is the negative electrode and the upper side thereof is the positive electrode. Thus, the degree of integration of the memory cell is limited.

The effects other than described above according to the third embodiment are the same as those of the first embodiment described above. It should be noted that, in the third embodiment, there has been shown an example where the heat treatment is applied in a reducing atmosphere or in a non-oxidizing atmosphere to grow the crystal grains of the polycrystalline conductive film 43; however, the heat treatment may be applied in an oxidizing atmosphere such as an oxygen atmosphere or a water vapor atmosphere. Thereby, since the crystal growth of the polycrystalline conductive film 43 is promoted and the height of the projections is increased, the operating voltage and operating current can be further reduced. However, if the heat treatment is applied in an oxidizing atmosphere, an oxide layer is formed on the surface of the polycrystalline conductive film 43. Thus, in order to suppress the formation of the oxide layer, it is preferable to set the partial pressure of the oxidizing agent to be used to 1 kPa or less, for example.

In the third embodiment, the polycrystalline conductive film 43 is formed of titanium nitride, but may be formed of doped silicon, for example. Furthermore, in the third embodiment, there has been shown an example where the diode 21 is provided in the lower portion of the pillar 16, and the resistance variable element 22 is provided in the upper portion of the pillar 16. However, the resistance variable element may be provided in the lower portion of the pillar, and the diode may be provided in the upper portion of the pillar. Still furthermore, the shape of the crystal grain 43a of the polycrystalline conductive film 43 is not limited to a rectangle, but may be a geometry of a corner portion pointing downward or a downward convex curved surface, as similar to the variations (see FIGS. 5A and 5B) of the first embodiment described above, for example.

Next, a fourth embodiment of the invention is described.

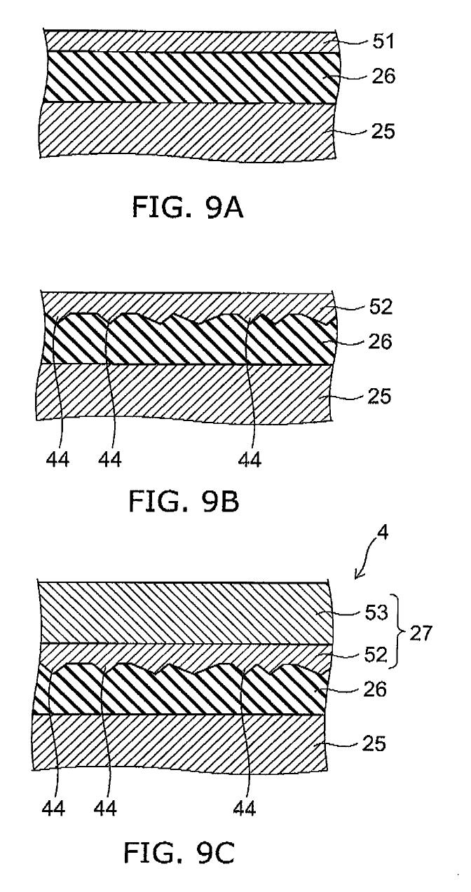

FIGS. 9A to 9C are process cross-sectional views illustrating a method of manufacturing a semiconductor memory device according to the fourth embodiment.

The configuration of a semiconductor memory device 4 according to the fourth embodiment is similar to that of the third embodiment. In the third embodiment described above, the distribution and shape of the projections 44 seen from the below correspond to those of the crystal grains of the polycrystalline conductive film 43. However, in the fourth embodiment, the distribution and shape of the projections 44 are not directly related to those of the crystal grains of the polycrystalline conductive film 43. In the fourth embodiment, a resistance variable film 26 is made of hafnium oxide containing zirconium, or titanium oxide containing zirconium, and a lower layer portion of an upper electrode 27 is made of zirconium silicide.

In the following, described is a production method of a resistance variable element, which is a part of the method of manufacturing a semiconductor memory device according to the fourth embodiment.

First, as shown in FIG. 9A, a lower electrode 25 is formed by depositing tungsten to a thickness of 100 nm by a PVD method, for example. Next, hafnium oxide containing zirconium of 1 to 20% by mass or titanium oxide containing zirconium of 1 to 20% by mass is deposited to a thickness of, for example, approximately 10 nm by a PVD or ALD method, for example, to form a resistance variable film 26 on the lower electrode 25. Then, silicon is deposited to a thickness of, for example, 1 to 5 nm by a PVD or CVD method, for example, to form a silicon film 51 on the resistance variable film 26.

Next, as shown in FIG. 9B, heat treatment is applied in a non-oxidizing atmosphere such as a nitrogen atmosphere or in a reducing atmosphere up to a temperature of e.g. 400 to 800° C. Thereby, silicon in the silicon film 51 reacts with zirconium in the resistance variable film 26 to form a zirconium silicide film 52. During the reaction, the interface between the resistance variable film 26 and the zirconium silicide film 52 becomes uneven. Thus, projections 44 are formed, which project downward and are buried in the resistance variable film 26.

The height and the formation density of the projections 44 can be controlled by adjusting the composition of the resistance variable film 26 and the condition for the above-mentioned heat treatment. Specifically, the higher the concentration of zirconium in the resistance variable film 26 is, the higher the projections 44 are formed. The higher the heat temperature is, the higher the projections 44 are formed. For example, the height of the projections 44 obtained at a heat temperature of 800° C. is 2 to 3 times higher than that obtained at 400° C. In addition, the longer the heating time is, the higher the projections 44 are formed. On the other hand, the shorter the heating time is, the higher the formation density of the projections 44 is obtained. For example, conventional heat treatment may produce a projection formation density of 1000 projections/μm² or more; however, if the above-mentioned heat treatment is applied by lamp heating or the like at a high temperature for a short time period, for example, at a heat temperature of approximately 800° C. for 1 to 100 seconds, the projection formation density can be increased to approximately 10000 projections/μm² with the height of the projections 44 being suppressed to 0.3 to 3 nm. In the fourth embodiment, the content of zirconium in the resistance variable film 26, the temperature and time for the heat treatment, and the like are adjusted in a way that the height of the projections becomes approximately 0.3 to 3 nm.

Next, as shown in FIG. 9C, a conductive film 53 is formed on the zirconium silicide film 52 by depositing tungsten to a thickness of 100 nm by a PVD method, for example. An upper electrode 27 is formed of the zirconium silicide film 52 and the conductive film 53. Subsequent processes of the manufacturing method are the same as those of the third embodiment described above.

Next, effects of the fourth embodiment are described.

In the fourth embodiment, since the zirconium silicide film 52 is formed in a lower layer portion of the upper electrode 27, the contact resistance between the resistance variable film 26 and the upper electrode 27 is low. Thus, the operating voltage can be further reduced. The effects other than described above according to the fourth embodiment are the same as those of the third embodiment described above.

It should be noted that, in the fourth embodiment, there may be formed a silicide reaction prevention layer, which has a nonuniform and considerably thin average thickness film, e.g., approximately 1 nm, between the resistance variable film 26 and the silicon film 51. As the silicide reaction prevention layer, a nitride layer such as silicon nitride layer, titanium nitride layer, or tungsten nitride layer, or an oxide layer such as silicon oxide layer or titanium oxide layer may be used, for example. With this layer, progress of the silicide reaction can be made nonuniform and the formation density of the projections can be increased. Nitrogen may also be introduced to the upper layer portion of the resistance variable film 26, and then a silicon film may be formed and undergo heat treatment. With this treatment, progress of the silicide reaction can also be made nonuniform and the formation density of the projections can be increased. In this case, the amount of nitrogen introduced may be small, for example, not larger than 1×10¹⁵ cm⁻² of concentration.

Next, a fifth embodiment of the invention is described.

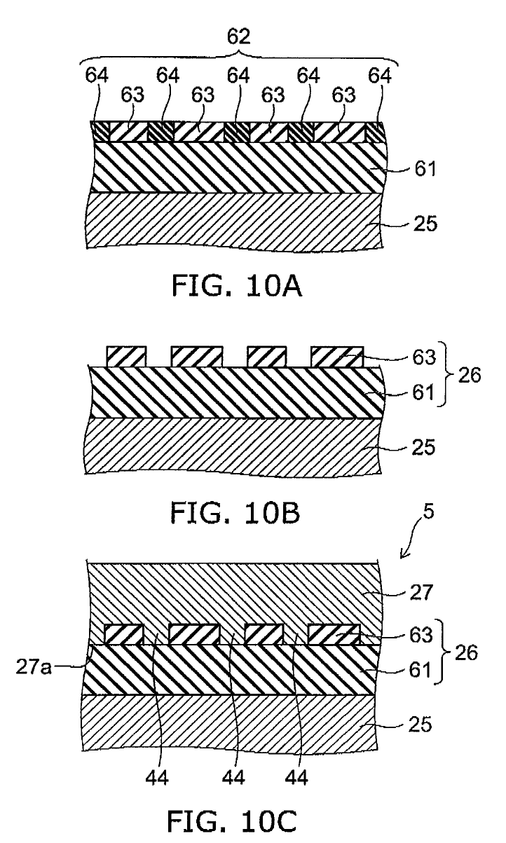

FIGS. 10A to 10C are process cross-sectional views illustrating a method of manufacturing a semiconductor memory device according to the fifth embodiment.

The configuration of a semiconductor memory device 5 according to the fifth embodiment is similar to that of the third embodiment. In the third embodiment described above, the distribution and shape of the projections 44 seen from the below correspond to those of the crystal grains of the polycrystalline conductive film 43. However, in the fifth embodiment, the distribution and shape of the projections 44 are not directly related to those of the crystal grains of the polycrystalline conductive film 43. In the fifth embodiment, the composition of portions located between the projections in the resistance variable film differs from the composition of the other portions in the resistance variable film.

In the following, described is a production method of a resistance variable element, which is a part of the method of manufacturing a semiconductor memory device according to the fifth embodiment.

First, as shown in FIG. 10A, a lower electrode 25 is formed by depositing tungsten to a thickness of 100 nm by a PVD method, for example. Next, nickel oxide is deposited to a thickness of 10 nm by a PVD method, for example, to form a base film 61 of a resistance variable film 26 on the lower electrode 25. Then, a metal silicate such as hafnium silicate is deposited to a thickness of approximately 1 to 5 nm by e.g. a PVD or ALD method to form a metal silicate film 62.

Subsequently, heat treatment is applied in a non-oxidizing atmosphere such as a nitrogen atmosphere or in a reducing atmosphere such as a hydrogen atmosphere at a temperature of e.g. 400 to 800° C. Thereby, the metal silicate film 62 is phase-separated into a portion 63 made of a metal oxide and a portion 64 made of silicon oxide. For example, when the metal silicate film 62 is made of hafnium silicate, the metal silicate film 62 is separated into a portion 63 made of hafnium oxide and a portion 64 made of silicon oxide.

At this stage, the widths of the portions 63 and 64 can be controlled by adjusting the composition of the metal silicate film 62. For example, if a nitrogen content of approximately 0.1 to 10% by mass is added to the metal silicate film 62, the widths of both the portions 63 and 64 are reduced. One example shows that the widths obtained when nitrogen is added is approximately ½ to 1/10 times the widths obtained when no nitrogen is added. The widths of the portions 63 and 64 can also be reduced by adding to the metal silicate film 62 a metal material, which is more difficult to be crystallized than the base metal material. For example, in the case that the metal silicate film 62 is formed of hafnium silicate, by adding approximately 0.1 to 10% by mass of aluminum (which is more difficult to be crystallized than hafnium, the base metal material), the widths of the portions 63 and 64 can be reduced to approximately ½ to 1/10 times the widths obtained when no aluminum is added. In the fifth embodiment, by controlling the composition of the metal silicate film 62, the width of the portion made of a metal oxide is approximately 2 to 10 nm and the width of the portion 64 made of silicon oxide is approximately 0.5 to 2 nm, for example.

Next, as shown in FIG. 10B, dry etching is performed in a hydrocarbon gas atmosphere to selectively remove the portion 64 made of silicon oxide. Accordingly, the resistance variable film 26 is now formed of the base film 61 made of nickel oxide and the portion 63 made of a metal oxide.

Next, as shown in FIG. 10C, an upper electrode 27 is formed on the base film 61 by depositing tungsten to a thickness of approximately 100 nm by a PVD method, for example. At this stage, tungsten, which forms the upper electrode 27, covers the portion 63 made of a metal oxide and fills the space where the portion 64 has been removed. The space filled with tungsten serves as a projection 44. Accordingly, the projection 44 is formed in a bottom surface 27a of the upper electrode 27. Subsequent processes of the manufacturing method are the same as those of the third embodiment described above. The configurations, manufacturing methods, and operations, other than described above, of the fifth embodiment are the same as those of the third embodiment described above.

In the fifth embodiment as well, the same effects similar as those in the third embodiment can be achieved. It should be noted that, in the fifth embodiment, there has been shown an example where hafnium silicate is used as the metal silicate, but the invention is not limited to this example. For example, since phase separation of a transition metal silicate easily occurs due to the heat treatment, such a silicate can be preferably used.

Next, a sixth embodiment of the invention is described.

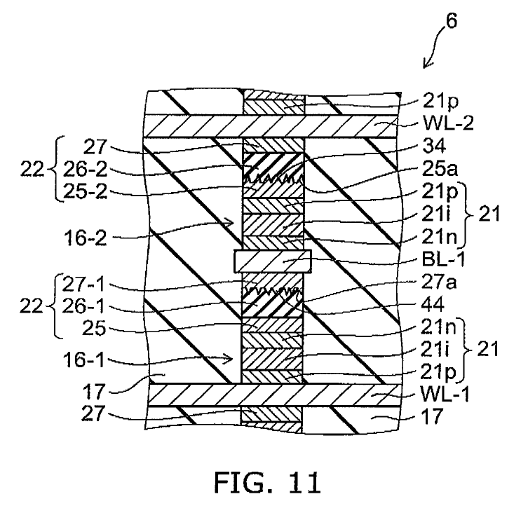

FIG. 11 is a cross-sectional view illustrating a portion of a semiconductor memory device according to the sixth embodiment.

The semiconductor memory device according to the sixth embodiment is a resistance random access memory (ReRAM).

The configuration of the semiconductor memory device according to the sixth embodiment is a combination of the first embodiment and the third embodiment described above.

As shown in FIG. 1, in the semiconductor memory device according to the sixth embodiment, similarly to the first embodiment described above, a memory cell portion 13 is provided on a silicon substrate 11 with an interlayer insulating film 12 interposed between the memory cell portion 13 and the silicon substrate 11. In the memory cell portion 13, word line wiring layers 14 and bit line wiring layers 15 are alternately stacked with an insulating layer 17 thereamong. Each of the word line wiring layers 14 includes multiple word lines WL extending in the word line direction, and each of the bit line wiring layers 15 includes multiple bit lines BL extending in the bit line direction. Also, a pillar 16 is provided at the portion where the distance between one word line WL and one bit line BL is the shortest. A diode 21 and a resistance variable element 22 are formed in each pillar 16, which serves as a memory cell.

As shown in FIG. 11, in each resistance variable element 22 of a semiconductor memory device 6 according to the sixth embodiment, there are formed projections, which project towards a resistance variable film 26, on an electrode of the bit line BL side, when seen from the resistance variable film 26. Specifically, of the resistance variable elements 22 connected to a certain bit line BL, one disposed above the bit line BL has a lower electrode 25 whose top surface 25a is provided with projections 34. On the other hand, the resistance variable element 22 disposed below the bit line BL has an upper electrode 27 whose bottom surface 27a is provided with projections 44. In other words, in any of the resistance variable elements 22, the projections are formed toward the word line WL from the bit line BL.

Specifically, now attention is focused on one word line WL-1 (first wiring) in the semiconductor memory device 6. In a pillar 16-1, which is provided between the word line WL-1 and a bit line BL-1 (second wiring) disposed one layer above the word line WL-1, there are provided a resistance variable film 26-1 and an upper electrode 27-1. The resistance variable film 26-1 is disposed above the word line WL-1 and connected to thereto. The upper electrode 27-1 is disposed on the resistance variable film 26-1 and has a bottom surface on which multiple projections 44 buried in the resistance variable film 26-1 are formed. The upper electrode 27-1 is connected to the bit line BL-1, which is disposed on the upper electrode 27-1. Meanwhile, in a pillar 16-2, which is provided between the bit line BL-1 and a word line WL-2 (third wiring) disposed one layer above the bit line BL-1, there are provided a lower electrode 25-2 and a resistance variable film 26-2. The lower electrode 25-2 is disposed above the bit line BL-1 and connected thereto, and has a top surface on which multiple projections 34 are provided. The projections 34 formed on the top surface of the lower electrode 25-2 are buried in the resistance variable film 26-2, which is disposed on the lower electrode 25-2. The resistance variable film 26-2 is connected to the word line WL-2 disposed thereabove.

The semiconductor memory device 6 according to the sixth embodiment can be manufactured by using a combination of the embodiments described above. Specifically, the above-mentioned pillar 16-1 can be produced according to any one of the third to fifth embodiments. Also, the pillar 16-2 can be produced according to the first embodiment or the second embodiment described above.

Next, the operation in the sixth embodiment is described.

In the semiconductor memory device 6, by selecting one word line WL and one bit line BL, a voltage is selectively applied to one pillar 16, which is connected between the lines. Then, by controlling the resistance state of the resistance variable element 22 provided in the pillar 16, data is written. A constant voltage is applied to the pillar 16 and the amount of an electric current flowing through the pillar 16 is measured. Thus, the resistance state of the resistance variable element 22 is detected and written data is read out.

In this case, a +5V electric potential is applied to one selected word line WL, and a 0V electric potential is applied to one selected bit line BL in the write operation, for example, so that a +5V voltage is applied to the pillar 16 connected between the lines. At this stage, to prevent the voltage from being applied to a pillar 16 between the selected word line WL and a non-selected bit line BL and to a pillar 16 between the selected bit line BL and a non-selected word line WL, a 0V electric potential, which is the same potential as that of the selected bit line BL, is applied to a non-selected word line WL, and a +5V electric potential, which is the same potential as that of the selected word line WL, is applied to a non-selected bit line BL. However, under this condition, a −5V voltage is applied to a pillar 16 connected between a non-selected word line WL and a non-selected bit line BL.

For this reason, the diode 21 is provided in each pillar 16 in such a manner that the direction from the word line WL to the bit line BL coincides with the forward direction of the diode 21. Thereby, a forward voltage is applied to the diode 21 in the selected pillar 16 and to the resistance variable element 22; meanwhile, no voltage is applied to a resistance variable element 22 in a non-selected pillar 16 connected between a non-selected word line WL and a non-selected bit line BL because a reverse voltage is applied to the diode 21. In this manner, any pillar 16 can be selected for operation.

At this stage, a voltage is applied in the selected pillar 16 with the word line WL serving as a positive electrode and the bit line BL serving as a negative electrode. Then, an electronic current flows from the bit line BL to the word line WL. In the semiconductor memory device 6, the projections are formed in the direction from the bit line BL to the word line WL. The projections are buried in the resistance variable film or an oxide film in contact with the resistance variable film. Accordingly, electric current paths can be easily formed in the resistance variable film. Thereby, the operating voltage and operating current can be reduced at any pillar 16.

Next, effects of the sixth embodiment are described.

According to the sixth embodiment, each wiring is shared by two memory cells where one is disposed above the wiring and the other is disposed below the wiring. Thus, a simple structured, highly integrated crosspoint-type ReRAM, which has less signal delay and allows a high speed operation, can be manufactured. When a positive electric potential is applied to the word line WL and a negative potential is applied to the bit line BL, a current path can be efficiently formed in the resistance variable film 26, and thus the operating voltage can be reduced. Consequently, memory malfunction due to an electric capacity or a leakage current between wirings can be avoided. Also, the manufacturing process can be simplified. The configurations, operations, and effects, other than described above, of the sixth embodiment are the same as those of the first embodiment described above.

In the above, the invention has been described with reference to the embodiments; however, the invention is not limited to these embodiments. Each of the embodiments described above can be implemented in combination with the other. Accordingly, since the operating voltage and operating current can be reduced regardless of the direction of the voltage applied to the pillar of each memory cell, design flexibility of the memory cell portion is increased and high integration of the memory cells is easily achieved. Various modifications such as addition/deletion of components, design change, addition/deletion of processes, or condition change, which are made on the embodiments described above by those skilled in the art are within the scope of the invention as long as the modifications fall within the spirit of the invention.

1. A semiconductor memory device comprising:
a lower electrode including a plurality of projections formed on a top surface thereof;
an oxide film covering the top surface and made of an oxide of a same metal as a metal contained in the lower electrode; and
a resistance variable film provided on the oxide film and being in contact with the oxide film,
the projections being buried in the oxide film, and a lower layer portion of the resistance variable film having an oxygen concentration lower than an oxygen concentration of a portion other than the lower layer portion of the resistance variable film.

2. The device according to claim 1, wherein the projections are formed of a subset of a plurality of crystal grains forming the top surface of the lower electrode, the subset projecting above the crystal grains surrounding the subset.

3. The device according to claim 1, wherein the projections are arranged along crystal grain boundaries of crystal grains forming the top surface of the lower electrode.

4. A semiconductor memory device comprising:
a resistance variable film; and
an upper electrode provided on the resistance variable film and including a plurality of projections formed on a bottom surface thereof,
the projections being buried in the resistance variable film.

5. The device according to claim 4, wherein the projections are formed of a subset of a plurality of crystal grains forming the bottom surface of the upper electrode, the subset projecting below the crystal grains surrounding the subset.

6. The device according to claim 4, wherein
the resistance variable film is made of any one of hafnium oxide containing zirconium and titanium oxide containing zirconium, and
a lower layer portion of the upper electrode is made of zirconium silicide.

7. A semiconductor memory device comprising:
a first wiring;
a first resistance variable film disposed above the first wiring and connected to the first wiring;
an upper electrode disposed on the first resistance variable film and including a plurality of projections formed on a bottom surface thereof, the projections being buried in the first resistance variable film;
a second wiring disposed on the upper electrode and connected to the upper electrode;
a lower electrode disposed above the second wiring, connected to the second wiring, and including a plurality of projections formed on a top surface of the lower electrode;
a second resistance variable film disposed on the lower electrode; and
a third wiring disposed above the second resistance variable film and connected to the second resistance variable film,
the projections formed on the top surface of the lower electrode being buried in the second resistance variable film.

8. The device according to claim 7, wherein an electric potential applied to the first wiring and the third wiring is higher than an electric potential of the second wiring during passing an electric current through the first resistance variable film and the second resistance variable film.

9. The device according to claim 7, further comprising an oxide film covering the top surface of the lower electrode and made of an oxide of a same metal as a metal contained in the lower electrode,
an oxygen concentration of a lower layer portion of the second resistance variable film being lower than an oxygen concentration of a portion other than the lower layer portion of the second resistance variable film.

10. A method of manufacturing a semiconductor memory device comprising:
forming an amorphous film on a conductive film;
forming a polycrystalline conductive film on the amorphous film; and
forming a resistance variable film containing oxygen on the polycrystalline conductive film and reacting an element contained in the polycrystalline conductive film with the oxygen contained in the resistance variable film while growing crystals of the polycrystalline conductive film.

11. The method according to claim 10, wherein the reacting includes heating the polycrystalline conductive film and the resistance variable film in any one of a non-oxidizing atmosphere and a reducing atmosphere.

12. A method of manufacturing a semiconductor memory device comprising:
forming an amorphous film on a conductive film;
forming a polycrystalline conductive film on the amorphous film;
nitriding at least crystal grain boundaries of the polycrystalline conductive film; and
forming a resistance variable film containing oxygen on the polycrystalline conductive film and reacting an element contained in the polycrystalline conductive film with the oxygen contained in the resistance variable film.

13. The method according to claim 12, wherein the nitriding at least the crystal grain boundaries of the polycrystalline conductive film includes heating the polycrystalline conductive film in a nitrogen monoxide gas atmosphere.

14. A method of manufacturing a semiconductor memory device comprising:
forming a resistance variable film; and
forming a polycrystalline conductive film on the resistance variable film and growing crystals of the polycrystalline conductive film.

15. The method according to claim 14, wherein a crystal structure of the resistance variable film is an amorphous structure.

16. A method of manufacturing a semiconductor memory device comprising:
forming a resistance variable film made of any one of hafnium oxide containing zirconium and titanium oxide containing zirconium;
forming a silicon film on the resistance variable film; and
reacting the zirconium in the resistance variable film with silicon in the silicon film.

17. The method according to claim 16, wherein the reacting includes heating the resistance variable film and the silicon film in any one of a non-oxidizing atmosphere and a reducing atmosphere.

18. A method of manufacturing a semiconductor memory device comprising:
forming a base film of a resistance variable film;
forming a metal silicate film on the base film;
phase-separating the metal silicate film into a portion made of a metal oxide and a portion made of silicon oxide by heating;
removing the portion made of the silicon oxide; and
forming an upper electrode on the base film to cover the portion made of the metal oxide.

19. The method according to claim 18, wherein the metal silicate film is formed of a transition metal silicate.

20. The method according to claim 19, wherein the metal silicate film is formed of hafnium silicate.
